(19) United States
(12) Patent Application Publication
(10) Pub. No.: US 2022/0205340 A1
(43) Pub. Date: Jun. 30, 2022

(54) UOE Pipe Casing Design Tool

(71) Applicant: Landmark Graphics Corporation, Houston, TX (US)

(72) Inventors: Zhengchun LIU, Houston, TX (US); Robello SAMUEL, Houston, TX (US); Adolfo GONZALES, Houston, TX (US); Max O. DUNCAN, Houston, TX (US); Jenny XIE, Houston, TX (US); Yongfeng KANG, Houston, TX (US)

(21) Appl. No.: 17/607,541

(22) PCT Filed: Jan. 2, 2020
(86) PCT No.: PCT/US2020/012066

§ 371 Date: Oct. 29, 2021

Related U.S. Application Data
(60) Provisional application No. 62/890,999, filed on Aug. 23, 2019.

(51) Int. Cl. E21B 41/00; G06F 30/10; E21B 47/07

(52) U.S. Cl. CPC E21B 41/00; E21B 2200/20; E21B 47/07; G06F 30/10

(57) ABSTRACT

A system for designing a casing string for an oil well, a gas well, an oil and gas well, and/or a geothermal well. The system comprises a processor, a non-transitory memory storing a casing string design, wherein the casing string design comprises at least one section of UOE-type pipe, a downhole environment simulation application stored in the non-transitory memory that, when executed by the processor determines downhole conditions based on the casing string design, wherein the downhole conditions comprise a downhole temperature, and a casing collapse strength modeling application stored in the non-transitory memory that, when executed by the processor, analyzes collapse strength of the casing string based on the downhole temperature and based on a UOE-type pipe collapse strength model and presents a collapse strength report on the casing string design based on analyzing the collapse strength of the casing string.

### CROSS-REFERENCE TO RELATED APPLICATIONS

None.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Oil wells are desirably cased with casing pipe to maintain the wellbore and promote installation and operation of production equipment. It is understood that the term oil well is used generally and can refer to any hole in the ground. The oil well may, during a production phase of its lifecycle, produce crude oil. The oil well may produce natural gas. The oil well may produce crude oil and natural gas in some combination or mixture. The oil well may produce hydrocarbons—either crude oil or natural gas or both—in combination with water Geothermal wells may likewise be cases with casing pipe.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is a block diagram of a computer system according to embodiments of the disclosure.

FIG. 2 is a flow chart of a method of designing a casing string for an oil well according to embodiments of the disclosure.

FIG. 3 is a flow chart of another method of designing a casing string for an oil well according to embodiments of the disclosure.

FIG. 4 is an illustration of an exemplary workflow for tubular design using UOE-type pipes according to embodiments of the disclosure.

FIG. 5 is an illustration of an exemplary casing string design in a wellbore according to embodiments of the disclosure.

FIG. 6 is an illustration of an exemplary presentation screen associated with an exemplary casing string design according to embodiments of the disclosure.

FIG. 7 is an illustration of an exemplary presentation screen associated with safety factors determined for an exemplary casing string design according to embodiments of the disclosure.

FIG. 8 is an illustration of an exemplary presentation screen associated with allowable casing wear determined for an exemplary casing string design according to embodiments of the disclosure.

FIG. 9 is an illustration of a collapse envelope associated with an exemplary casing string design according to embodiments of the disclosure.

FIG. 10 is a block diagram of an exemplary computer system according to embodiments of the disclosure.

### DETAILED DESCRIPTION

It should be understood at the outset that although illustrative implementations of one or more embodiments are illustrated below, the disclosed systems and methods may be implemented using any number of techniques, whether currently known or not yet in existence. The disclosure should in no way be limited to the illustrative implementations, drawings, and techniques illustrated below, but may be modified within the scope of the appended claims along with their full scope of equivalents.

Casing pipe is subjected to a variety of mechanical and chemical stresses over its lifetime, and casing pipe may desirably be designed for a specific wellbore to be robust and resist failure over its operating life due to any of those stresses. UOE-type pipe is formed by bending a continuous rectangular sheet of steel first into a U-shape, pressing the sheet into an O-shape, longitudinally welding the seam, and expanding the pipe to improve the circularity of the pipe. The pipes and tubulars formed using the UOE process are often used in pipelines at the surface where temperature and pressure factors are not significant in analyzing safety of the piping design. The UOE pipe forming process can make large diameter pipe very economically, making UOE pipe desirable for use in casing wellbores. Recently, well design engineers are trying to replace traditional API 5CT pipes with cheaper API-5L pipes in the downhole wellbore casing construction. Typical API-5L grades include A, B, X-42, X52, X60, X65, X70, X80, and X90. API-5L line pipe is typically manufactured by UOE method. A drawback of piping formed with the UOE pipe forming process, however, is that UOE pipe exhibits a lower collapse strength relative to oil country tubular goods (OCTG) pipe, and traditional downhole casing string design procedures do not currently apply to such UOE pipe. A need therefore exists for a design tool for determining collapse strength of UOE pipe for use in downhole environments.

The present disclosure teaches an automated computer-based tool for analyzing downhole environments and calculating safety factors of a proposed casing string based on the analysis of the downhole environments using a UOE-type pipe collapse strength model. In embodiments, the UOE-type pipe collapse strength model takes into account downhole temperature, downhole internal pressure, and tension on the pipe. As described further hereinafter, the downhole temperature, downhole internal pressure, and tension are incorporated into a modification of traditional calculation of yield strength. While the disclosure describes examples related to analyzing UOE-type pipe collapse strength, it is contemplated that the teachings of the present disclosure may also be advantageously applied to other types of longitudinally welded seam pipe. For example, it is contemplated that the teachings of the present disclosure may advantageously be applied to pipes manufactured by a process, distinct from the UOE process, that entails forming of metal sheets into a generally ovoid shape, longitudinally welding the joined sheet ends, and expanding the formed ovoid to achieve a more circular cross sectional shape.

The automated computer-based tool estimates environmental parameters including temperature, external pressure, internal pressure, and tension that will be experienced at each of a plurality of points along a casing string deployed in a specific wellbore. These calculation points can be specified by a user of the tool. A user may specify the calculations be made every meter, every 30 feet, every 100 feet, or some other periodic interval. In embodiments, the user may further specify that the calculations be made at specific points of interest in the casing string, for example 0.1 feet above the top of the cement (TOC) of surface casing and 0.1 feet below TOC. A downhole environment simulation application of the automated computer-based tool may determine these estimated environmental parameters based in part on a casing string design and based in part on an input file providing parameters of the borehole and proximate subterranean formations. In embodiments, temperature and pressure downhole environmental parameters may be obtained from a thermal flow simulation for each of the plurality of calculation points along the casing string in the wellbore. For further details about estimating downhole environmental parameters such as temperature and pressure, see U.S. patent application Ser. No. 15/359,397, filed Nov. 22, 2016, entitled “Vector-ratio Safety Factors for Wellbore Tubular Design,” by Zhengchun Liu, et al, which is incorporated herein by reference in its entirety.

The automated computer-based tool may determine safety factors of the casing string in each of a plurality of different operating modes for the casing string using different strength models. For example, the automated computer-based tool may determine safety factors for an initial condition of casing segment installation (it is noted casing strings may be deployed in segments, where different segments may be installed at different times), green cement test operating mode, a mud drop of 50% operating mode, an overpull operating mode, a 1-year of production operating mode, and other operating modes. The automated computer-based tool may determine safety factors using a triaxial strength model, using a burst strength model, using a collapse strength model, and using an axial strength model. The automated computer-based tool may determine safety factors using each model, for each different operating mode, at each point in the casing string where environmental conditions are determined by the downhole environment simulation application. The collapse strength may be analyzed by a casing collapse strength modeling application of the automated computer-based tool. In embodiments, the casing collapse strength modeling application employs a modified American Petroleum Institute (API) Recommended Practice (RP) 1111 collapse strength model that incorporates temperature effects, pressure effects, and tension effects on analyzing casing collapse strength.

The results include a large number of safety factors. The worst case safety factors (lowest safety factor) at each of a plurality of user specified points along the casing string are tabulated and presented in a safety factor table.

The safety factor information can be used by a casing designer to evaluate the casing design. If safety factors are adequate, the casing design may be deemed safe. If safety factors are too large, the casing design may be deemed safe but over-built and hence inefficient. If any safety factor value is inadequate, the casing design may be deemed unsafe, and the casing designer may desirably adjust his or her casing design and repeat the determination of downhole conditions and the analysis of safety factors.

A challenge is present in that while computer implemented models exist to help 1design and virtually test designs for downhole casing they are ill suited for addressing UOE pipe used for casing because of different characteristics (particularly in collapse strength) of UOE pipe. At the same time, computer implemented models exist regarding characteristics of UOE pipe but are designed for pipeline use and do not account for downhole condition and particularly do not adequately address downhole temperature, downhole pressure, and tensions in a downhole configuration. In an effort to resolve this challenge the disclosure provides a novel combination of downhole condition simulation and testing but using a casing model derived from a pipeline model for UOE pipe which then includes extra steps of adjusting strength based on downhole temperature and adjusting the calculations for yield strength to specifically account for the axial stress and the internal pressure in the downhole context as derived or provided by the overall model. As a result four distinct approaches are combined through a modified computer implementation with modified inputs, new tables, modified constraints, and an enhanced output (which may also address ovality as a constraining factor along with pipe grade and wall thickness).

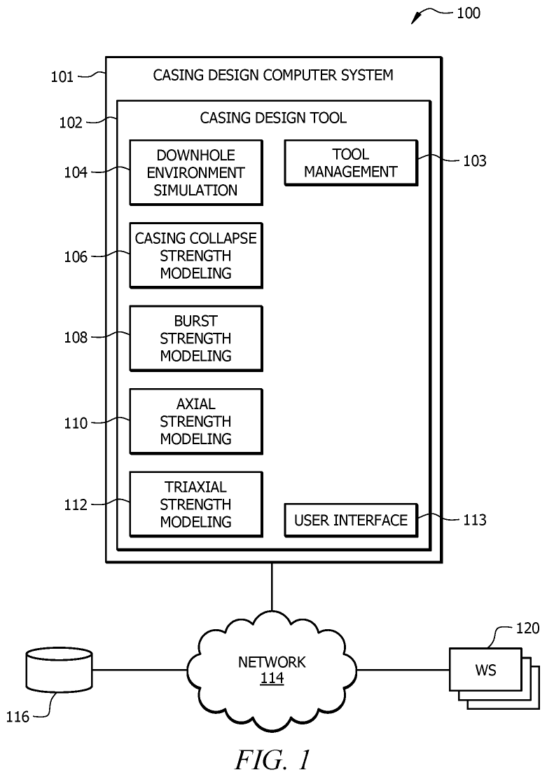

Turning now to FIG. 1, a computer system 100 is described. In embodiments, the computer system 100 comprises a casing design tool 102 that executes a downhole environment simulation application 104 and a casing collapse strength modeling application 106. The casing design tool 102 executes on a casing design computer system 101. In embodiments, the casing design tool 102 also executes a burst strength modeling application 108, an axial strength modeling application 110, and a triaxial strength modeling application 112. The casing design tool 102 may be implemented as a computer system. Computer systems are described further hereinafter. In an embodiment, the casing design tool 102 further comprises a tool management application 103 that manages execution of the applications 104, 106, 108, 110, 112 and provides for sharing of selected data among the applications 104, 106, 108, 110, 112. The tool management application 103 may also collect results from the applications 104, 106, 108, 110, 112 and generate a summary report of analysis of a casing design and present the summary report in one or multiple different forms amenable to human understanding on a computer screen. The casing design tool 102 further comprises a user interface 113 that may be provided to human users, for example users who use workstations 120. The human user (e.g., a casing string designer) may use the presentation on the computer screen to iteratively modify a casing string design to achieve both safety goals and economic efficiency goals.

The casing design tool 102 is communicatively coupled to a network 114, wherein the network 114 comprises one or more private networks, one or more public networks, or a combination thereof. The system 100 further comprises one or more work stations 120. The work stations 120 may be used by casing designers to specify a casing design, to specify a wellbore structure and parameters of the wellbore, and to interact with user interfaces of the casing design tool 102. A data store 116 stores information used by the casing design tool 102 and information produced by the casing design tool 102.

A wellbore structure may be defined in a data file that is stored in the data store 116. For example, a work station 120 may be used to define and store the wellbore structure in a data file and store it in the data store 116. For example, a file defining the wellbore structure may be imported from a different computer system (not shown) and stored in the data store 116. The definition of the wellbore structure may define one or more of a wellbore depth or length, a trajectory of the wellbore, a diameter at different points along the wellbore, formations that abut the wellbore, temperatures at different points along the wellbore. It is understood that the data store 116 may store both wellbore definitions, casing design definitions, and casing design analysis results for a plurality of different oil wells.

One or more casing string designs may be stored in the data store. A casing string design may identify a plurality of different casing components where each casing component may comprise one or more sections. For example a casing string design may identify a conductor casing component, a surface casing component, an intermediate casing component, a protective casing component, a production liner component, a production tieback component, and a production tubing component. An intermediate casing component may comprise a plurality of sections, where each different section may have different characteristics, for example different pipe thickness. The casing string design may identify lengths of each casing component and/or each section of each casing component. The casing string design may identify an outside diameter and a thickness and a pipe type of each casing component and/or each section of each casing component. The casing string design may identify location of hangers associated with casing components. The casing string design may identify cement depths associated with casing components—for example a base of cement depth and a top of cement (TOC) depth of a casing component. The casing string design may identify a wellbore hole size associated with the casing string components. The casing string design may identify a type of annulus fluid in the casing string components. The casing string design may identify other particulars of the casing string design.

The downhole environment simulation application 104 may analyze the wellbore structure of an oil well and the casing string design and estimate environmental parameters at different points in the wellbore. For example, temperature of the casing string when it is deployed in the wellbore at different points may be estimated. For example, internal and external pressures experienced by the casing string at different points may be estimated. Tension loads on the casing string at different points may be estimated by a stress analysis application in conjunction with the downhole environment simulation application. The downhole environmental parameters estimated by the downhole environment simulation application 104 at different points may be stored in the data store 116, for example in a data file. In some contexts, downhole environmental parameters estimated by the simulation application 104 may be said to be determined by the simulation application 104.

The casing collapse strength modeling application 106 may analyze the downhole environmental parameters to determine collapse strength safety factors at different points along the casing string design responsive to collapse loads (e.g., pressure outside the casing is greater than pressure inside the casing). The burst strength modeling application 108 may analyze the downhole environmental parameters to determine burst strength safety factors at different points along the casing string design responsive to burst loads (e.g., pressure inside the casing is greater than pressure outside the casing). The axial strength modeling application 110 may analyze the downhole environmental parameters to determine axial strength safety factors at different points along the casing string design responsive to axial loads on the casing. The triaxial strength modeling application 112 may analyze the downhole environmental parameters to determine triaxial strength safety factors at different points along the casing string design responsive to triaxial loads on the casing.

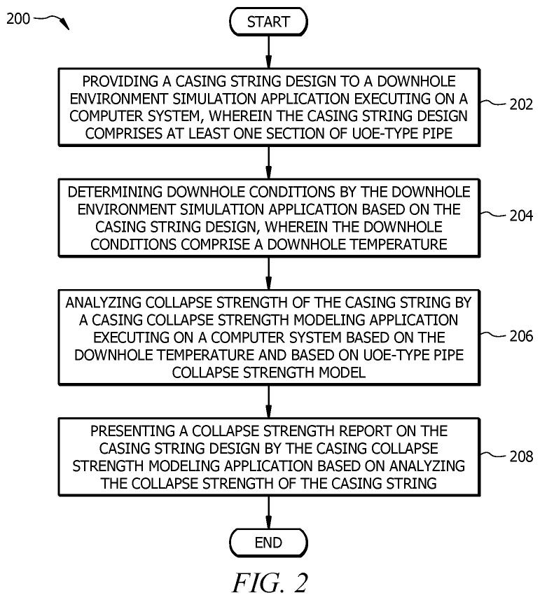

Turning now to FIG. 2, a method 200 is described. In embodiments, the method 200 is a method of designing a casing string for an oil well. It is understood that the term oil well is used generally and can refer to any hole in the ground. The oil well may, during a production phase of its lifecycle, produce crude oil. The oil well may produce natural gas. The oil well may produce crude oil and natural gas in some combination or mixture. The oil well may produce hydrocarbons—either crude oil or natural gas or both—in combination with water. In embodiments, the method 200 is a method of designing a casing string for an oil/gas well or geothermal well. In embodiments, the method 200 is a method of designing a casing string for a geothermal well.

At block 202, the method 200 comprises providing a casing string design to a downhole environment simulation application executing on a computer system, wherein the casing string design comprises at least one section of UOE-type pipe. At block 204, the method 200 comprises determining downhole conditions by the downhole environment simulation application based on the casing string design, wherein the downhole conditions comprise a downhole temperature. In an embodiment, the processing of block 204 may comprise the downhole environment simulation application determining a plurality of downhole temperatures, for example downhole temperatures at different locations along the section of UOE-type pipe. The processing of block 204 may also be referred to as estimating downhole conditions, for example estimating or projecting downhole conditions that may be experienced by the casing string when it is deployed in the wellbore at a future time. At block 206, the method 200 comprises analyzing collapse strength of the casing string by a casing collapse strength modeling application executing on a computer system based on the downhole temperature and based on a UOE-type pipe collapse strength model. In embodiments, the processing of block 206 take downhole temperature, downhole tension loads, and downhole pressure effects on the casing string, where the casing string is at least partially built using UOE-type pipe.

At block 208, the method 200 comprises presenting a collapse strength report on the casing string design by the casing collapse strength modeling application based on analyzing the collapse strength of the casing string. The method 200 may be used by a casing string designer or engineer to design a casing string for a specific wellbore that is safe and is economically efficient. The steps of the method 200 may be reiterated, adapting one or more parts of the casing string design to meet a safety factor constraint at one point and to meet an economic efficiency objective at another point in the casing string design. It is desirable to design a casing string that is safe in all operational modes, over the design lifecycle of the casing string, without entailing excess costs associated with overdesigning the casing string. In embodiments, method 200 is performed by the casing design tool 102. In embodiments, the method 200 is performed by the downhole environment simulation application 104 and the casing collapse strength modeling application 106 described above with reference to FIG. 1.

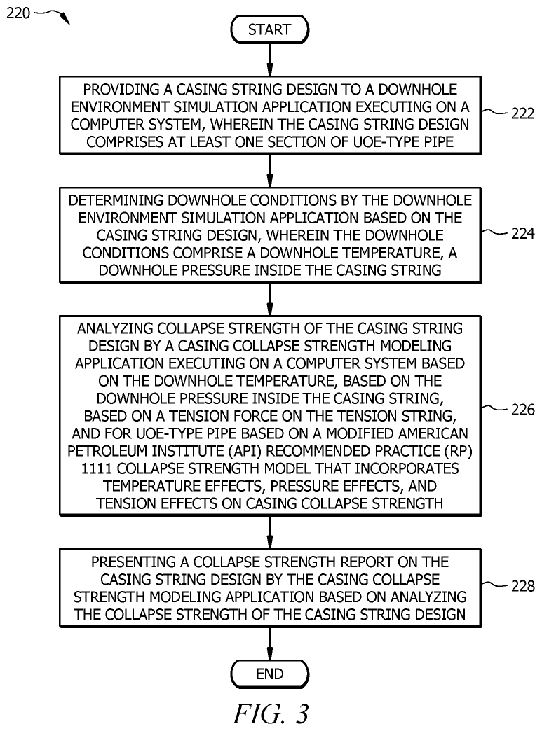

Turning now to FIG. 3, a method 220 is described. In embodiments, the method 220 may be a method of designing a casing string for an oil well. In embodiments, the method 220 may be a method of designing a casing string for a geothermal well. At block 222, the method 220 comprises providing a casing string design to a downhole environment simulation application executing on a computer system, wherein the casing string design comprises at least one section of UOE type pipe.

At block 224, the method 220 comprises determining downhole conditions by the downhole environment simulation application based on the casing string design, wherein the downhole conditions comprise a downhole temperature, a downhole pressure inside the casing string. In an embodiment, the processing of block 224 comprises the downhole environment simulation application determining a plurality of downhole temperatures and/or a plurality of downhole pressures inside the casing string. Determining downhole conditions may comprise estimating or projecting downhole conditions when a casing string is deployed in a specific wellbore at a future time. At block 226, the method 220 comprises analyzing collapse strength of the casing string design by a casing collapse strength modeling application executing on a computer system based on the downhole temperature, based on the downhole pressure inside the casing string, based on a tension force on the casing string, and for UOE-type pipe based on a modified American Petroleum Institute (API) Recommended Practice (RP) 1111 collapse strength model that incorporates temperature effects, pressure effects, and tension effects on casing collapse strength. The downhole temperature, the downhole pressure, and the tension force on the casing string may be parameter values determined or estimated by the downhole environment simulation application.

At block 228, the method 220 comprises presenting a collapse strength report on the casing string design by the casing collapse strength modeling application based on analyzing the collapse strength of the casing string design. A casing string designer or engineer may iterate the processing of method 220 multiple times adapting various elements of a casing string design, adapting based on the collapse strength report. The processing of block 228 may further comprise presenting other results of analysis of the casing string based on the estimated or projected downhole conditions. For example, maximum wear analysis reports may be provided. In embodiments, method 220 is performed by the casing design tool 102. In embodiments, the method 220 is performed by the downhole environment simulation application 104 and the casing collapse strength modeling application 106 described above with reference to FIG. 1.

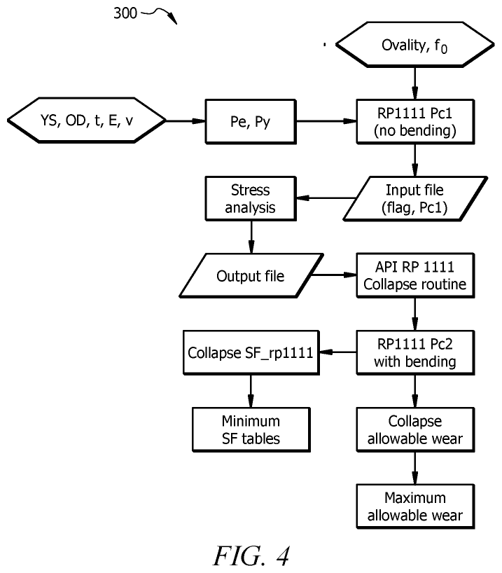

In embodiments, the steps for UOE collapse strength analysis (see also FIG. 4) may comprise:
1. GUI dialogues are presented to promote the casing designer selecting UOE type pipe collapse analysis. For example, API RP1111 collapse analysis may be selected.
2. obtain ovality—The default ovality value can be calculated using OD tolerances in API 5L.
3. calculate RP1111 nominal collapse rating (without bending), see Eq. 14;
4. deliver the nominal RP1111 collapse rating to stress analysis engine;
5. stress analysis return the results DLS, Fa, etc.;
6. calculate the collapse SF using RP1111 collapse formula (with bending, Eq. 1) for each grid point using ovality and returned DLS data;
7. calculate the max. allowable wear by solving wear % in the following equation:

RP1111 ratings with bending(wear %)=collapse load*DF.
8. results update: collapse SF-involved tables, Casing wear allowance table/plot, Max Allowable Wear table/plot, Design Limits plot—The collapse envelope will be changed because of API RP1111 collapse strength formula.
9. Every safety factor view (plot/table/ratings dialog) shows a new comment or flag indicating RP1111 in use.

The collapse rating of UOE pipe may be calculated using the following formula:

$$Δ {P}_{r a t i n g} = {f}_{c} {P}_{c} [ g ( δ ) - \frac{{f}_{1} {ɛ}_{max}}{{ɛ}_{b}} ] \qquad ( 1 )$$

The above equation is based on API RP1111 (5th edition) collapse design equation (13) as follows:

$$\frac{ɛ}{{ɛ}_{b}} + \frac{{P}_{o} - {P}_{i}}{{f}_{c} {P}_{c}} \leq g ( δ ) \qquad ( 2 )$$

Equations (1) and (2) are for pipes under both external pressure load and bending strain. In the equations, fc is the collapse factor for use with combined pressure and bending loads, by default fc is given by equation (3) as:

$$f c = f 0 / g ( δ ) \qquad ( 3 )$$

f0 is the factor of safety, f0=0.6 for cold expanded pipe (default), =0.7 for seamless or electric resistance welded (ERW) pipe, g(δ) is the collapse reduction factor given by equation (4) as:

$$g ( δ ) = 1 / ( 1 + 20 δ ) \qquad ( 4 )$$

where δ is API ovality given by equation (5) as:

$$δ = \frac{{D}_{max} - {D}_{min}}{{D}_{max} + {D}_{min}} \qquad ( 5 )$$

Dmax is the maximum diameter at any given cross-section, in inches; Dmin is the minimum diameter at any given cross-section, in inches; ε_{b}=t/(2D) is the buckling strain under pure bending, and ε is the allowable bending strain in the pipe given by equation (6) as:

$$ɛ = {f}_{1} {ɛ}_{max} \qquad ( 6 )$$

f₁ is the bending safety factor, default value=2.0; εₘₐₓ is the maximum installation or in-place bending strain, which is calculated using wellbore curvature (K=1/R, in rad/inches) data and is given by equation (7) as:

$${ɛ}_{max} = K \frac{D}{2} \qquad ( 7 )$$

In embodiments, K takes the wellbore dogleg severity value expressed in units of °/100 foot at a certain depth.

$${ɛ}_{max} = Conv \cdot DLS \frac{D}{2} \qquad ( 8 )$$

Cony=(π/180)(100)(12) is a unit conversion factor from °/100 ft to rad/inch. Pc is the collapse pressure of the pipe in psi.

$$\begin{matrix}{P}_{C} = \frac{{P}_{y} + {P}_{e}}{\sqrt{{P}_{y}^{2} + {P}_{e}^{2}}} & ( 9 ) \\ {P}_{y} = 2 {YS}^{′} ( \frac{t}{D} ) & ( 10 ) \\ {P}_{e} = 2 E \frac{{( \frac{t}{D} )}^{3}}{( 1 - {v}^{3} )} & ( 11 )\end{matrix}$$

Where Pe is the elastic collapse pressure of the pipe in psi, Py is the yield collapse pressure in psi, YS′ is the equivalent yield strength of the pipe steel in psi, t is the pipe nominal wall thickness, in inches, D is the pipe nominal outer diameter, in inches, E is the Young's modulus in psi, default value=3.0×10⁷ psi, v is Poisson's ratio, default value=0.3. YS+ can be calculated using API 5C3 formula 42 and temperature-derated steel grade.

$${YS}^{′} = \{ {[ 1 - 0.75 {( \frac{{σ}_{a} + {p}_{i}}{{f}_{y m n}} )}^{2} ]}^{1 / 2} - 0.5 \frac{( {σ}_{a} + {p}_{i} )}{{f}_{y m n}} \} {f}_{y m n} γ \qquad ( 12 )$$

Where fymn is the minimum yield strength of the steel in the pipe and where γ is a value in the range of 0.75 to 1.0 that derates the strength based on temperature, aa is the axial stress on the pipe and pi is the internal pressure of the pipe. At standard temperature, in embodiments, the value of γ may be 1.0, at a high temperature, the value of γ may be 0.75. In other embodiments, the value of γ at a high temperature may be 0.87. In embodiments, γ is defined for temperatures in the range 68 F to 500 F by equation 13 as:

$$γ = ( - 0.000300 \; 95 ) t + 1.02 \; 046 \qquad ( 13 )$$

In other embodiments, the value of γ may be determined differently. For example, different types of steel may be associated with different temperature derating relationships. Thus equation 12 adapts the yield strength based on temperature, based on internal pressure, and based on axial tension.

For collapse only load without bending, ε=0, Eq. (2) becomes

$${f}_{0} {P}_{c} \geq {P}_{o} - {P}_{i} \qquad ( 14 )$$

Which is the design equation (9) in API RP111 (5^{th} edition) for collapse due to external pressure.

Turning now to FIG. 4 an exemplary workflow 300 is depicted. It comprises the aforementioned steps 2 through 7 for UOE collapse strength analysis. YS refers to yield strength, and OD refers to outer diameter. E is Young's modulus while v is Poisson's ratio. SF is the abbreviation of safety factor.

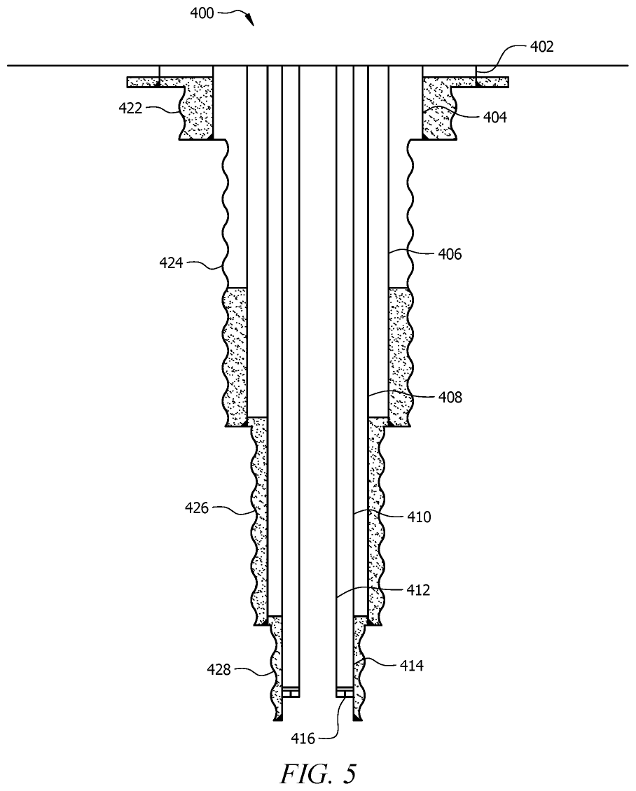

Turning now to FIG. 5, an exemplary casing string is illustrated. The casing string 400 comprises a conductor casing 402, a surface casing 406, an intermediate casing 408, a protective casing 410, a production tubing 412, a production liner 414, and a latched permanent packer 416. The casing string 400 is partially secured in the wellbore with a first cement zone 422, a second cement zone 424, a third cement zone 426, and a fourth cement zone 428. The design of a casing string will identify the components or elements of the casing string, the lengths of the casing string components, the diameter of the casing string components, the grade of pipe used, cement level associated with the casing string components, and other factors. The casing string is illustrated deployed in a wellbore. The wellbore may be associated with an oil well. The wellbore may be associated with a geothermal well.

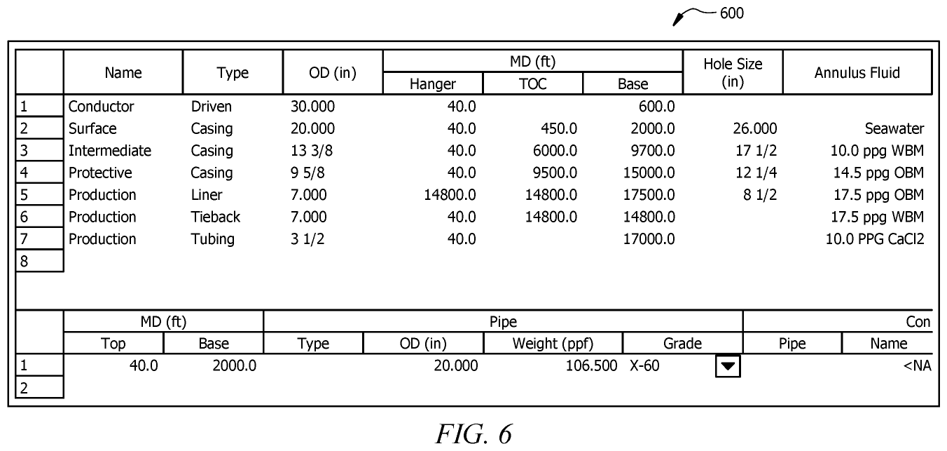

Turning now to FIG. 6, a table 600 is illustrated that presents some of the details of an exemplary casing string design are shown. In the example of FIG. 6, the surface casing has been selected, and further details of the surface casing are shown in a lower table that includes a pipe grade selection box. In embodiments, the table 600 can be used to define the casing string design. In other embodiments, the table 600 is primarily a presentation of the casing string design which has been defined in another window, in another tool, or in an input file to the casing design tool 102.

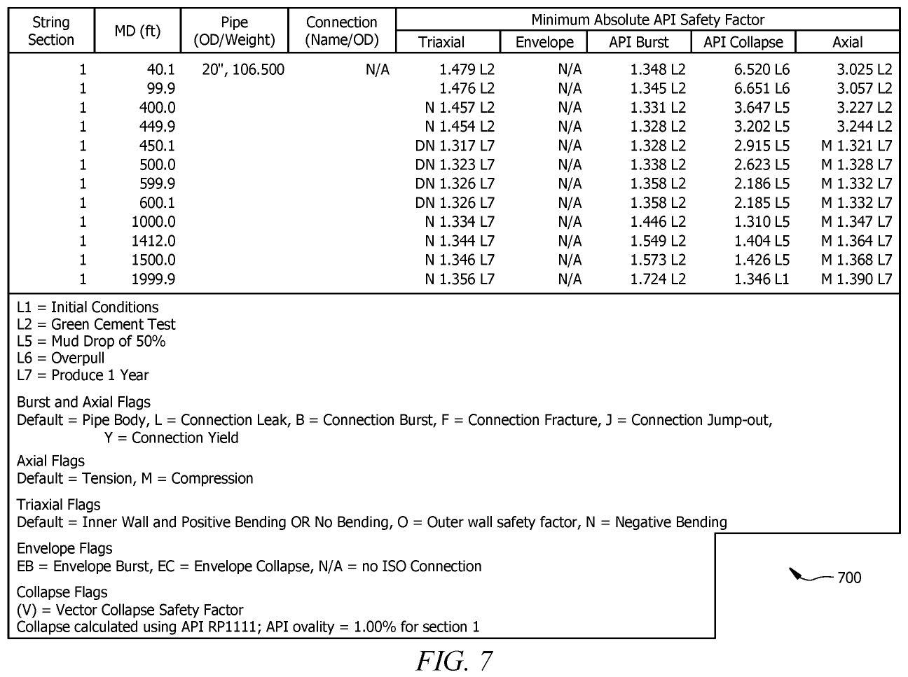

Turning now to FIG. 7, an exemplary safety factors table 700 is illustrated that presents some details of safety factor analysis of an exemplary casing string design. At each of a plurality of depths of the casing string design for the surface casing using UOE pipe (e.g., the table 700 only relates to one casing string component—to see the safety factors of other casing string components, that component needs to be selected for presentation), the worst case safety factor values for each of triaxial strength, axial strength, burst strength, and collapse strength are presented. The safety factors may be determined by the triaxial strength modeling application 112, the axial strength modeling application 110, the burst strength modeling application 108, and the collapse strength modeling application 106 operating on the downhole environmental parameters determined by the downhole environment simulation application 104 and based on the casing string design. The worst case safety factor values are associated with an indication of an operating mode in which the worst case safety factor value appeared. For example, a worst case safety factor may be associated with a green cement test operation mode. For example, a worst case safety factor may be associated with a mud drop of 50% operating mode. As a result of using the modified API RP 1111 strength model that incorporates temperature effects, pressure effects, and tension effects, the safety factor results presented in table 700 are different from and more accurate than the safety factor results that would be determined without taking temperature, pressure, and tension effects into account in the downhole environment. The more accurate results promote increased safety and more efficient casing string designs. If the safety factors all exceed 1.0, the casing string design is deemed to be safe. If any single safety factor is equal or less than 1.0, the casing string design ought to be adapted and reanalyzed to achieve adequate safety factors in all operating modes and for all casing segments and casing components.

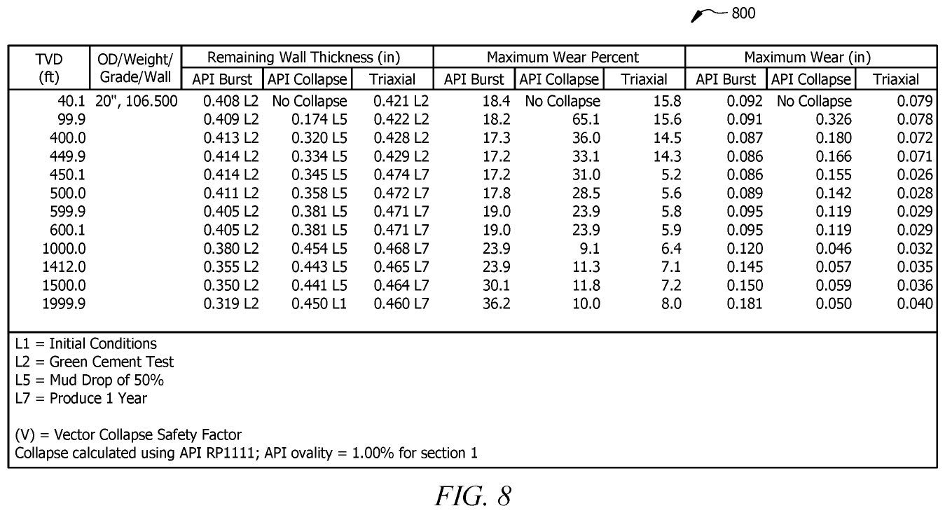

Turning now to FIG. 8, an exemplary maximum allowable wear table 800 is discussed. The values in the table 800 present wear states that correspond to maximum allowable wear while remaining safe from a pipe failure for an exemplary surface casing of UOE pipe. The casing string designer can employ these analysis results determined by the strength analysis applications 106, 108, 112 in combination with lifecycle pipe wear modeling to determine a maximum life of the casing string. If the maximum life is not sufficient, the designer may adapt the casing string design to overcome the one or more limitations on casing life to achieve the maximum life objective, for example by selecting a thicker diameter pipe for the surface casing.

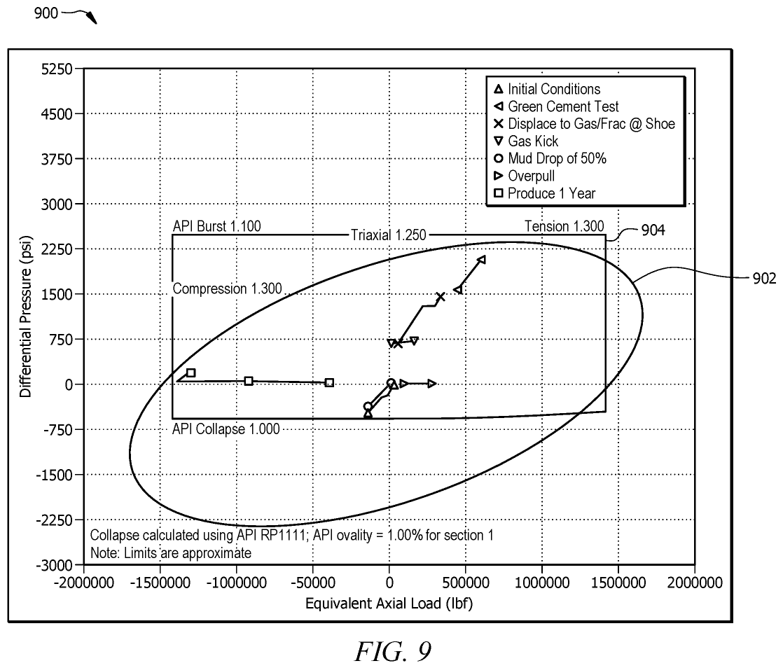

Turning now to FIG. 9, an exemplary design limits plot shows failure envelopes for an exemplary surface casing using UOE pipe. The oval collapse envelope 902 is an envelope representing triaxial failure. The rectangular envelope 904 represents the failure boundaries provided by axial, burst, and collapse strength analyses. If the casing string is operated within both envelopes, the casing string design for the surface casing of UOE pipe is safe. The information depicted in FIG. 9 is a graphical representation of the same results information presented in tabular form in FIG. 7.

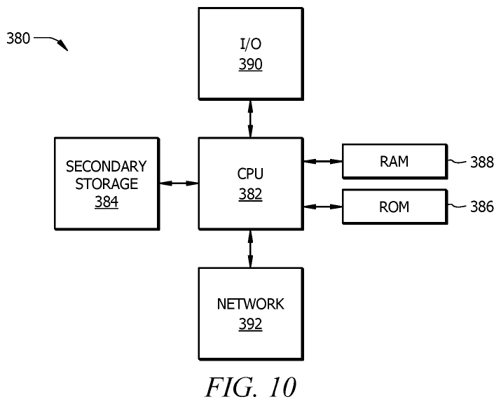

FIG. 10 illustrates a computer system 380 suitable for implementing one or more embodiments disclosed herein. The computer system 380 includes a processor 382 (which may be referred to as a central processor unit or CPU) that is in communication with memory devices including secondary storage 384, read only memory (ROM) 386, random access memory (RAM) 388, input/output (I/O) devices 390, and network connectivity devices 392. The processor 382 may be implemented as one or more CPU chips.

It is understood that by programming and/or loading executable instructions onto the computer system 380, at least one of the CPU 382, the RAM 388, and the ROM 386 are changed, transforming the computer system 380 in part into a particular machine or apparatus having the novel functionality taught by the present disclosure. It is fundamental to the electrical engineering and software engineering arts that functionality that can be implemented by loading executable software into a computer can be converted to a hardware implementation by well-known design rules. Decisions between implementing a concept in software versus hardware typically hinge on considerations of stability of the design and numbers of units to be produced rather than any issues involved in translating from the software domain to the hardware domain. Generally, a design that is still subject to frequent change may be preferred to be implemented in software, because re-spinning a hardware implementation is more expensive than re-spinning a software design. Generally, a design that is stable that will be produced in large volume may be preferred to be implemented in hardware, for example in an application specific integrated circuit (ASIC), because for large production runs the hardware implementation may be less expensive than the software implementation. Often a design may be developed and tested in a software form and later transformed, by well-known design rules, to an equivalent hardware implementation in an application specific integrated circuit that hardwires the instructions of the software. In the same manner as a machine controlled by a new ASIC is a particular machine or apparatus, likewise a computer that has been programmed and/or loaded with executable instructions may be viewed as a particular machine or apparatus.

Additionally, after the system 380 is turned on or booted, the CPU 382 may execute a computer program or application. For example, the CPU 382 may execute software or firmware stored in the ROM 386 or stored in the RAM 388. In some cases, on boot and/or when the application is initiated, the CPU 382 may copy the application or portions of the application from the secondary storage 384 to the RAM 388 or to memory space within the CPU 382 itself, and the CPU 382 may then execute instructions that the application is comprised of. In some cases, the CPU 382 may copy the application or portions of the application from memory accessed via the network connectivity devices 392 or via the I/O devices 390 to the RAM 388 or to memory space within the CPU 382, and the CPU 382 may then execute instructions that the application is comprised of. During execution, an application may load instructions into the CPU 382, for example load some of the instructions of the application into a cache of the CPU 382. In some contexts, an application that is executed may be said to configure the CPU 382 to do something, e.g., to configure the CPU 382 to perform the function or functions promoted by the subject application. When the CPU 382 is configured in this way by the application, the CPU 382 becomes a specific purpose computer or a specific purpose machine.

The secondary storage 384 is typically comprised of one or more disk drives or tape drives and is used for non-volatile storage of data and as an over-flow data storage device if RAM 388 is not large enough to hold all working data. Secondary storage 384 may be used to store programs which are loaded into RAM 388 when such programs are selected for execution. The ROM 386 is used to store instructions and perhaps data which are read during program execution. ROM 386 is a non-volatile memory device which typically has a small memory capacity relative to the larger memory capacity of secondary storage 384. The RAM 388 is used to store volatile data and perhaps to store instructions. Access to both ROM 386 and RAM 388 is typically faster than to secondary storage 384. The secondary storage 384, the RAM 388, and/or the ROM 386 may be referred to in some contexts as computer readable storage media and/or non-transitory computer readable media.

I/O devices 390 may include printers, video monitors, liquid crystal displays (LCDs), touch screen displays, keyboards, keypads, switches, dials, mice, track balls, voice recognizers, card readers, paper tape readers, or other well-known input devices.

The network connectivity devices 392 may take the form of modems, modem banks, Ethernet cards, universal serial bus (USB) interface cards, serial interfaces, token ring cards, fiber distributed data interface (FDDI) cards, wireless local area network (WLAN) cards, radio transceiver cards, and/or other well-known network devices. The network connectivity devices 392 may provide wired communication links and/or wireless communication links (e.g., a first network connectivity device 392 may provide a wired communication link and a second network connectivity device 392 may provide a wireless communication link). Wired communication links may be provided in accordance with Ethernet (IEEE 802.3), Internet protocol (IP), time division multiplex (TDM), data over cable system interface specification (DOCSIS), wave division multiplexing (WDM), and/or the like. In an embodiment, the radio transceiver cards may provide wireless communication links using protocols such as code division multiple access (CDMA), global system for mobile communications (GSM), long-term evolution (LTE), WiFi (IEEE 802.11), Bluetooth, Zigbee, narrowband Internet of things (NB IoT), near field communications (NFC), radio frequency identity (RFID),. The radio transceiver cards may promote radio communications using 5G, 5G New Radio, or 5G LTE radio communication protocols. These network connectivity devices 392 may enable the processor 382 to communicate with the Internet or one or more intranets. With such a network connection, it is contemplated that the processor 382 might receive information from the network, or might output information to the network in the course of performing the above-described method steps. Such information, which is often represented as a sequence of instructions to be executed using processor 382, may be received from and outputted to the network, for example, in the form of a computer data signal embodied in a carrier wave.

Such information, which may include data or instructions to be executed using processor 382 for example, may be received from and outputted to the network, for example, in the form of a computer data baseband signal or signal embodied in a carrier wave. The baseband signal or signal embedded in the carrier wave, or other types of signals currently used or hereafter developed, may be generated according to several methods well-known to one skilled in the art. The baseband signal and/or signal embedded in the carrier wave may be referred to in some contexts as a transitory signal.

The processor 382 executes instructions, codes, computer programs, scripts which it accesses from hard disk, floppy disk, optical disk (these various disk based systems may all be considered secondary storage 384), flash drive, ROM 386, RAM 388, or the network connectivity devices 392. While only one processor 382 is shown, multiple processors may be present. Thus, while instructions may be discussed as executed by a processor, the instructions may be executed simultaneously, serially, or otherwise executed by one or multiple processors. Instructions, codes, computer programs, scripts, and/or data that may be accessed from the secondary storage 384, for example, hard drives, floppy disks, optical disks, and/or other device, the ROM 386, and/or the RAM 388 may be referred to in some contexts as non-transitory instructions and/or non-transitory information.

In an embodiment, the computer system 380 may comprise two or more computers in communication with each other that collaborate to perform a task. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. In an embodiment, virtualization software may be employed by the computer system 380 to provide the functionality of a number of servers that is not directly bound to the number of computers in the computer system 380. For example, virtualization software may provide twenty virtual servers on four physical computers. In an embodiment, the functionality disclosed above may be provided by executing the application and/or applications in a cloud computing environment. Cloud computing may comprise providing computing services via a network connection using dynamically scalable computing resources. Cloud computing may be supported, at least in part, by virtualization software. A cloud computing environment may be established by an enterprise and/or may be hired on an as-needed basis from a third party provider. Some cloud computing environments may comprise cloud computing resources owned and operated by the enterprise as well as cloud computing resources hired and/or leased from a third party provider.

In an embodiment, some or all of the functionality disclosed above may be provided as a computer program product. The computer program product may comprise one or more computer readable storage medium having computer usable program code embodied therein to implement the functionality disclosed above. The computer program product may comprise data structures, executable instructions, and other computer usable program code. The computer program product may be embodied in removable computer storage media and/or non-removable computer storage media. The removable computer readable storage medium may comprise, without limitation, a paper tape, a magnetic tape, magnetic disk, an optical disk, a solid state memory chip, for example analog magnetic tape, compact disk read only memory (CD-ROM) disks, floppy disks, jump drives, digital cards, multimedia cards, and others. The computer program product may be suitable for loading, by the computer system 380, at least portions of the contents of the computer program product to the secondary storage 384, to the ROM 386, to the RAM 388, and/or to other non-volatile memory and volatile memory of the computer system 380. The processor 382 may process the executable instructions and/or data structures in part by directly accessing the computer program product, for example by reading from a CD-ROM disk inserted into a disk drive peripheral of the computer system 380. Alternatively, the processor 382 may process the executable instructions and/or data structures by remotely accessing the computer program product, for example by downloading the executable instructions and/or data structures from a remote server through the network connectivity devices 392. The computer program product may comprise instructions that promote the loading and/or copying of data, data structures, files, and/or executable instructions to the secondary storage 384, to the ROM 386, to the RAM 388, and/or to other non-volatile memory and volatile memory of the computer system 380.

In some contexts, the secondary storage 384, the ROM 386, and the RAM 388 may be referred to as a non-transitory computer readable medium or a computer readable storage media. A dynamic RAM embodiment of the RAM 388, likewise, may be referred to as a non-transitory computer readable medium in that while the dynamic RAM receives electrical power and is operated in accordance with its design, for example during a period of time during which the computer system 380 is turned on and operational, the dynamic RAM stores information that is written to it. Similarly, the processor 382 may comprise an internal RAM, an internal ROM, a cache memory, and/or other internal non-transitory storage blocks, sections, or components that may be referred to in some contexts as non-transitory computer readable media or computer readable storage media.

### Additional Disclosure

The following are non-limiting, specific embodiments in accordance with the present disclosure:

A first embodiment, which is a method of designing a casing string for an oil/gas well or geothermal well, comprising providing a casing string design to a downhole environment simulation application executing on a computer system, wherein the casing string design comprises at least one section of UOE-type pipe, determining downhole conditions by the downhole environment simulation application based on the casing string design, wherein the downhole conditions comprise a downhole temperature, analyzing collapse strength of the casing string by a casing collapse strength modeling application executing on a computer system based on the downhole temperature and based on a UOE-type pipe collapse strength model; and presenting a collapse strength report on the casing string design by the casing collapse strength modeling application based on analyzing the collapse strength of the casing string.

A second embodiment, which is the method of the first embodiment, comprising analyzing a triaxial strength of the casing string by a triaxial strength modeling application executing on a computer system and presenting a triaxial strength report on the casing string design based on analyzing the triaxial strength of the casing string.

A third embodiment, which is the method of the first or the second embodiment, comprising analyzing an axial strength of the casing string by an axial strength modeling application executing on a computer system and presenting an axial strength report on the casing string design based on analyzing the axial strength of the casing string.

A fourth embodiment, which is the method of the first, the second, or the third embodiment, comprising analyzing a burst strength of the casing string by a burst strength modeling application executing on a computer system and presenting a burst strength report on the casing string design based on analyzing the burst strength of the casing string.

A fifth embodiment, which is the method of the first, the second, the third, or the fourth embodiment, wherein the analyzing the collapse strength of the casing string is further based on a downhole pressure determined by the downhole environment simulation application.

A sixth embodiment, which is the method of the first, the second, the third, the fourth, or the fifth embodiment, wherein analyzing the collapse strength of the casing string is further based on a tension on the casing determined by the downhole environment simulation application.

A seventh embodiment, which is the method of the first, the second, the third, the fourth, or the fifth embodiment, further comprising analyzing casing string wear limits based on the downhole conditions.

An eighth embodiment, which is a system for designing a casing string for an oil well, comprising a processor, a non-transitory memory storing a casing string design, wherein the casing string design comprises at least one section of UOE-type pipe, a downhole environment simulation application stored in the non-transitory memory that, when executed by the processor determines downhole conditions based on the casing string design, wherein the downhole conditions comprise a downhole temperature; and a casing collapse strength modeling application stored in the non-transitory memory that, when executed by the processor analyzes collapse strength of the casing string based on the downhole temperature and based on a UOE-type pipe collapse strength model, and presents a collapse strength report on the casing string design based on analyzing the collapse strength of the first casing string.

A ninth embodiment, which is the system of the eighth embodiment, further comprising a burst strength modeling application stored in the non-transitory memory that, when executed by the processor, analyzes burst strength of the casing string based on the downhole conditions and presents a burst strength report on the casing string design.

A tenth embodiment, which is the system of the eighth or the ninth embodiment, further comprising an axial strength modeling application stored in the non-transitory memory that, when executed by the processor, analyzes axial strength of the casing string based on the downhole conditions and presents an axial strength report on the casing string design.

An eleventh embodiment, which is the system of the eighth, the ninth, or the tenth embodiment, further comprising a triaxial strength modeling application stored in the non-transitory memory that, when executed by the processor, analyzes triaxial strength of the casing string based on the downhole conditions and presents a triaxial strength report on the casing string design.

A twelfth embodiment, which is the system of the eighth, the ninth, the tenth, or the eleventh embodiment, wherein the analyzing the collapse strength of the casing string is further based on a downhole pressure determined by the downhole environment simulation application.

A thirteenth embodiment, which is the system of the eighth, the ninth, the tenth, the eleventh, or the twelfth embodiment, wherein the analyzing the collapse strength of the casing string is further based on a tension on the casing string determined by the downhole environment simulation application.

A fourteenth embodiment, which is the system of the eighth, the ninth, the tenth, the eleventh, the twelfth, or the thirteenth embodiment, wherein the casing collapse strength modeling application further analyzes casing string wear limits based on the downhole conditions.

A fifteenth embodiment, which is a method of designing a casing string for an oil well, comprising providing a casing string design to a downhole environment simulation application executing on a computer system, wherein the casing string design comprises at least one section of UOE-type pipe, determining downhole conditions by the downhole environment simulation application based on the casing string design, wherein the downhole conditions comprise a downhole temperature, a downhole pressure inside the casing string, analyzing collapse strength of the casing string design by a casing collapse strength modeling application executing on a computer system based on the downhole temperature, based on the downhole pressure inside the casing string, based on a tension force on the casing string, and for UOE-type pipe based on a modified American Petroleum Institute (API) Recommended Practice (RP) 1111 collapse strength model that incorporates temperature effects, pressure effects, and tension effects on casing collapse strength, and presenting a collapse strength report on the casing string design by the casing collapse strength modeling application based on analyzing the collapse strength of the casing string design.

A sixteenth embodiment, which is the method of the fifteenth embodiment, wherein the modified API RP 1111 collapse strength model further incorporates pipe ovality.

A seventeenth embodiment, which is the method of the fifteenth embodiment, further comprising changing at least one element of the casing string design and repeating the steps of determining downhole conditions by the simulation application, analyzing the collapse strength of the casing string using the modified casing string design, and presenting an updated collapse strength report.

An eighteenth embodiment, which is the method of the fifteenth embodiment, wherein the downhole temperature comprises a plurality of downhole temperatures.

A nineteenth embodiment, which is the method of the eighteenth embodiment, wherein the downhole pressure comprises a plurality of downhole pressures.

A twentieth embodiment, which is the method of the fifteenth embodiment, further comprising analyzing casing string wear limits based on the downhole conditions.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented.

Also, techniques, systems, subsystems, and methods described and illustrated in the various embodiments as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

What is claimed is:

1. A method of designing a casing string for an oil/gas well or geothermal well, comprising:
providing a casing string design to a downhole environment simulation application executing on a computer system, wherein the casing string design comprises at least one section of UOE-type pipe;
determining downhole conditions by the downhole environment simulation application based on the casing string design, wherein the downhole conditions comprise a downhole temperature;
analyzing collapse strength of the casing string by a casing collapse strength modeling application executing on a computer system based on the downhole temperature and based on a UOE-type pipe collapse strength model; and
presenting a collapse strength report on the casing string design by the casing collapse strength modeling application based on analyzing the collapse strength of the casing string.

2. The method of claim 1, comprising analyzing a triaxial strength of the casing string by a triaxial strength modeling application executing on a computer system and presenting a triaxial strength report on the casing string design based on analyzing the triaxial strength of the casing string.

3. The method of claim 1, comprising analyzing an axial strength of the casing string by an axial strength modeling application executing on a computer system and presenting an axial strength report on the casing string design based on analyzing the axial strength of the casing string.

4. The method of claim 1, comprising analyzing a burst strength of the casing string by a burst strength modeling application executing on a computer system and presenting a burst strength report on the casing string design based on analyzing the burst strength of the casing string.

5. The method of claim 1, wherein the analyzing the collapse strength of the casing string is further based on a downhole pressure determined by the downhole environment simulation application.

6. The method of claim 1, wherein analyzing the collapse strength of the casing string is further based on a tension on the casing determined by the downhole environment simulation application.

7. The method of claim 1, further comprising analyzing casing string wear limits based on the downhole conditions.

8. A system for designing a casing string for an oil well, comprising:
a processor;
a non-transitory memory storing a casing string design, wherein the casing string design comprises at least one section of UOE-type pipe;
a downhole environment simulation application stored in the non-transitory memory that, when executed by the processor determines downhole conditions based on the casing string design, wherein the downhole conditions comprise a downhole temperature; and
a casing collapse strength modeling application stored in the non-transitory memory that, when executed by the processor
analyzes collapse strength of the casing string based on the downhole temperature and based on a UOE-type pipe collapse strength model; and
presents a collapse strength report on the casing string design based on analyzing the collapse strength of the first casing string.

9. The system of claim 8, further comprising a burst strength modeling application stored in the non-transitory memory that, when executed by the processor, analyzes burst strength of the casing string based on the downhole conditions and presents a burst strength report on the casing string design.

10. The system of claim 8, further comprising an axial strength modeling application stored in the non-transitory memory that, when executed by the processor, analyzes axial strength of the casing string based on the downhole conditions and presents an axial strength report on the casing string design.

11. The system of claim 8, further comprising a triaxial strength modeling application stored in the non-transitory memory that, when executed by the processor, analyzes triaxial strength of the casing string based on the downhole conditions and presents a triaxial strength report on the casing string design.

12. The system of claim 8, wherein the analyzing the collapse strength of the casing string is further based on a downhole pressure determined by the downhole environment simulation application.

13. The system of claim 8, wherein the analyzing the collapse strength of the casing string is further based on a tension on the casing string determined by the downhole environment simulation application.

14. The system of claim 8, wherein the casing collapse strength modeling application further analyzes casing string wear limits based on the downhole conditions.

15. A method of designing a casing string for an oil well, comprising:
providing a casing string design to a downhole environment simulation application executing on a computer system, wherein the casing string design comprises at least one section of UOE-type pipe;
determining downhole conditions by the downhole environment simulation application based on the casing string design, wherein the downhole conditions comprise a downhole temperature, a downhole pressure inside the casing string;
analyzing collapse strength of the casing string design by a casing collapse strength modeling application executing on a computer system based on the downhole temperature, based on the downhole pressure inside the casing string, based on a tension force on the casing string, and for UOE-type pipe based on a modified American Petroleum Institute (API) Recommended Practice (RP) 1111 collapse strength model that incorporates temperature effects, pressure effects, and tension effects on casing collapse strength; and
presenting a collapse strength report on the casing string design by the casing collapse strength modeling application based on analyzing the collapse strength of the casing string design.

16. The method of claim 15, wherein the modified API RP 1111 collapse strength model further incorporates pipe ovality.

17. The method of claim 15, further comprising changing at least one element of the casing string design and repeating the steps of determining downhole conditions by the simulation application, analyzing the collapse strength of the casing string using the modified casing string design, and presenting an updated collapse strength report.

18. The method of claim 15, wherein the downhole temperature comprises a plurality of downhole temperatures.

19. The method of claim 18, wherein the downhole pressure comprises a plurality of downhole pressures.

20. The method of claim 15, further comprising analyzing casing string wear limits based on the downhole conditions.
